(19) United States
(12) Patent Application Publication
(10) Pub. No.: US 2025/0105789 A1
(43) Pub. Date: Mar. 27, 2025

(54) AMPLIFIER WITH SOURCE DEGENERATION

(71) Applicant: MACRONIX INTERNATIONAL CO., LTD., Hsinchu (TW)

(72) Inventors: Shang-Chi YANG, Changhua (TW); Tung-Yu LI, Taoyuan (TW); Jian-Syu LIN, Chiayi (TW)

(73) Assignee: MACRONIX INTERNATIONAL CO., LTD., HSINCHU (TW)

(21) Appl. No.: 18/371,217

(22) Filed: Sep. 21, 2023

(51) Int. Cl. H03F 1/02; H03F 3/45

(52) U.S. Cl. CPC H03F 1/02; H03F 3/45179; H03F 2200/498

(57) ABSTRACT

A differential amplifier includes an input pair of transistors with a source-side resistor circuit, having a transistor biased in a triode region, and a current source. The resistor circuit in combination with a capacitance, causes source degeneration in the amplifier. The source side resistor circuit includes a first MOS transistor having a first channel terminal connected to the source of a first transistor in the differential pair, and a second channel terminal connected to the bulk terminal, and a second MOS transistor having a first channel terminal connected to the source of a second transistor in the differential pair, and a second channel terminal connected to the bulk terminal. A bias circuit biases the first MOS transistor and the second MOS transistor in a triode region. The resistance of the source-side resistor circuit and the gain of the transistors in the differential amplifier can track across process corners.

### BACKGROUND

### Field

A technology described herein relates to differential amplifiers, and to equalizer circuits utilizing differential amplifiers.

### Description of Related Art

Input signals for integrated circuits can have very high frequencies, on the order of gigahertz in some cases. Communication channels which deliver the input signals can suffer channel loss, particularly at high frequencies. Accordingly, receivers in these environments often include high-speed input buffers having equalizer circuits to compensate for channel loss, and to provide for uniform gain across wide input frequencies. One type of equalizer has been referred to as a continuous time linear equalizer CLTE, which can be based on a differential amplifier with source degeneration. Source degeneration can be tuned to improve the AC gain at the operating frequencies for the equalizers, including at frequencies on the order of gigahertz.

In integrated circuit manufacturing, so-called process corner variations can impact the operating characteristics of circuits on the chips. Thus, a problem encountered in the manufacturing of equalizer circuits used in the receivers on integrated circuits, and other differential amplifier base circuits, relates to maintaining operating characteristics across process corners.

It is desirable to provide improved circuit structures that can be more stable across process corners for high-frequency equalizers and differential amplifiers.

### SUMMARY

An amplifier including an input pair of transistors with a source-side resistor circuit is described. The source-side resistor circuit includes a transistor biased in a triode region. The source-side resistor circuit in combination with a capacitance, causes source degeneration in the amplifier with an improved gain at a target frequency. The resistance of the source-side resistor circuit and the gain of the transistors in the differential amplifier can track across process corners.

An amplifier circuit is described comprising an input pair of transistors, the transistors in the pair having respective source, drain, gate and bulk terminals. A source side resistor circuit is connected to the sources of the transistors in the input pair. The source side resistor circuit includes a first MOS transistor having a first channel terminal connected to the source of a first transistor in the differential pair, and a second channel terminal connected to the bulk terminal, and a second MOS transistor having a first channel terminal connected to the source of a second transistor in the differential pair, and a second channel terminal connected to the bulk terminal. A bias circuit to bias the first MOS transistor and the second MOS transistor in a triode region is described.

An equalizer circuit is described with good uniformity in compensation across a target frequency range, using an input pair with a source-side resistor circuit which includes a transistor biased in a triode region.

An input buffer for a high speed data channel is described using an equalizer circuit like that described herein.

Other aspects and advantages of the present technology can be seen on review of the drawings, the detailed description and the claims, which follow.

### BRIEF DESCRIPTION OF THE DRAWINGS

FIG. 1 is a simplified diagram of a communication channel including an equalizer with an input pair having a source-side resistor circuit.

FIG. 2 is a circuit diagram for an example of a differential amplifier having a source-side resistor circuit.

FIG. 3 is a circuit diagram for an example of a continuous time linear equalizer circuit having an input pair configured as a differential amplifier, with a source-side resistor circuit.

FIG. 4 is a circuit diagram of a bias circuit for the equalizer circuit of FIG. 3.

FIG. 5 is a graph illustrating “peaking gain”.

FIGS. 6A, 6B and 6C provide a circuit diagram for an example of a differential amplifier having a source-side resistor circuit with two pairs of transistors with corresponding bias circuits.

FIG. 7 is a circuit diagram for an example of a differential amplifier having a source-side resistor circuit with three pairs of transistors.

### DETAILED DESCRIPTION

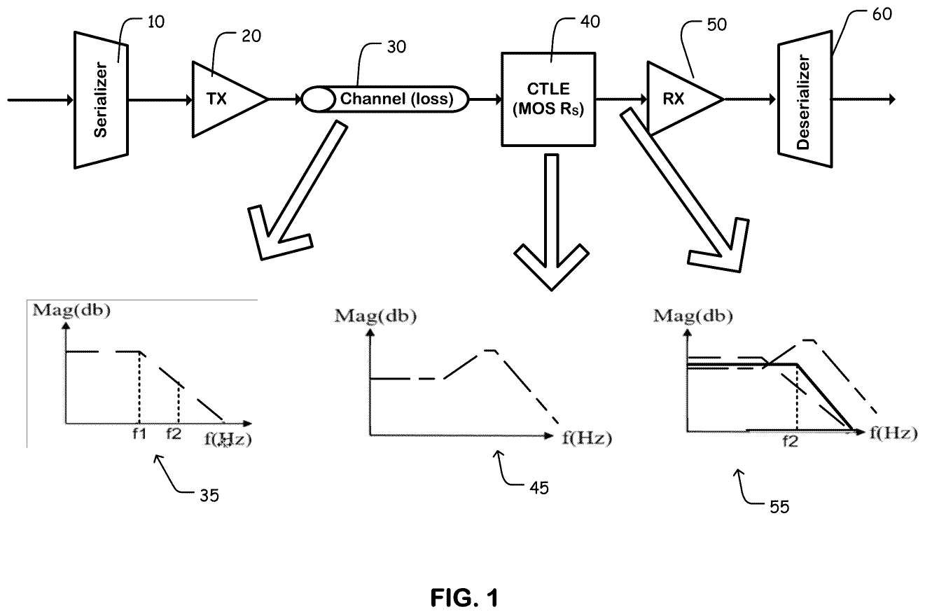

A detailed description of embodiments of the present invention is provided with reference to the FIGS. 1-7.

FIG. 1 is a simplified diagram of a communication channel such as can be used in integrated circuit systems. A transmit side of the channel includes serializer 10, the output of which is applied to a transmitter circuit 20. The transmitter circuit 20 applies a signal to a channel circuit 30, which can include a transmission line. The channel circuit 30 is connected to a high-speed input buffer at the destination device. In this example, the high-speed input buffer includes a continuous time linear equalizer CTLE circuit 40, the output of which is applied to a receiver circuit 50. The output of the receiver circuit 50 can be applied to a deserializer 60, delivering input data to the destination device.

The channel circuit 30 can have a low pass filter response, causing channel loss at high frequency as represented by the graph 35 showing signal magnitude in decibels dB versus frequency. Thus, in a target frequency range between f₁ and f₂, the signal gain can fall in accordance with a low pass filter response of the channel. The equalizer circuit 40 can compensate for low pass filter response of the channel by providing gain in the target frequency range as represented by the graph 45. Characteristics of the signal at the output of the equalizer circuit 40 can be seen in the graph 55, resulting from a combination of the low pass filter characteristic of the channel, with the gain characteristics of the equalizer. The signal can have uniform gain across the target frequency range between frequencies f1 and f2.

In systems as described herein, the equalizer circuit 40 includes an input pair of transistors having a source-side resistor circuit that includes a transistor biased on the triode region (MOS R_{S}). The input pair can be configured as a differential amplifier. The differential amplifier is configured to amplify the difference between two input signals while rejecting the part of the signal common to both inputs. The source-side resistor circuit provides source degeneration. The gain of the transistors in the input pair can track the resistance of the resistor circuit across process corners, sometimes referred to as fast-fast ff, typical-typical tt and slow-slow ss corners.

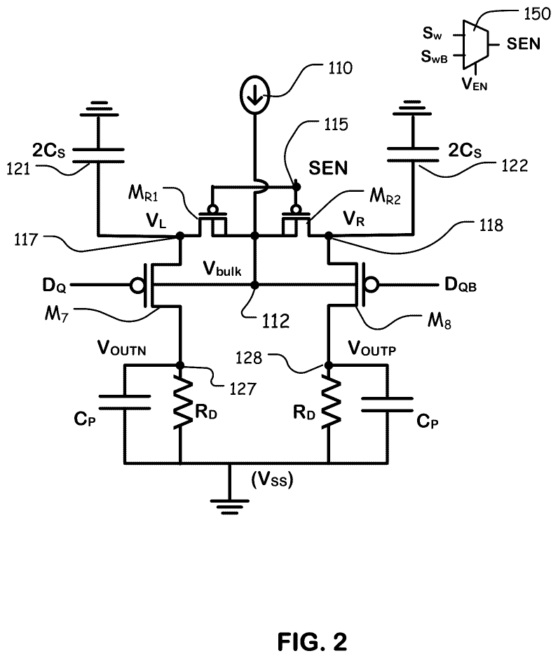

FIG. 2 is a circuit diagram for a differential amplifier including a resistor circuit configured as a source side resistance. The circuit includes an input pair of P-channel transistors M₇ and M₈ having source terminals at nodes 117 and 118, respectively. Nodes 117 and 118 have voltages V_{L} and V_{R}, respectively. The resistor circuit includes P-channel transistors M_{R1} and M_{R2}. Transistor M_{R1} has a first channel terminal (i.e., source/drain terminal) connected to the node 117 and a second channel terminal connected to the output of the current source 110 at node 112. Transistor M_{R2} has a first channel terminal connected to node 118 and a second channel terminal connected to node 112. Node 112 is connected to the output of the current source 110. Also, the channel bodies, or semiconductor “bulk”, of the transistors M₇ and M₈ of the input pair, and of the transistors M_{R1} and M_{R2} of the resistor circuit, are connected to node 112. The voltage at node 112 is labeled V_{bulk}. When transistor M_{R1} is on in a triode region, V_{L} is equal to V_{bulk}−(V_{DS} of M_{R1}). Also, when transistor M_{R2} is on in a triode region, V_{R} is equal to V_{bulk}−(V_{DS} of M_{R2}). When operated in the triode region, the drain to source voltage V_{DS} of transistors M_{R1} and M_{R2} varies linearly with V_{L} and V_{R} respectively.

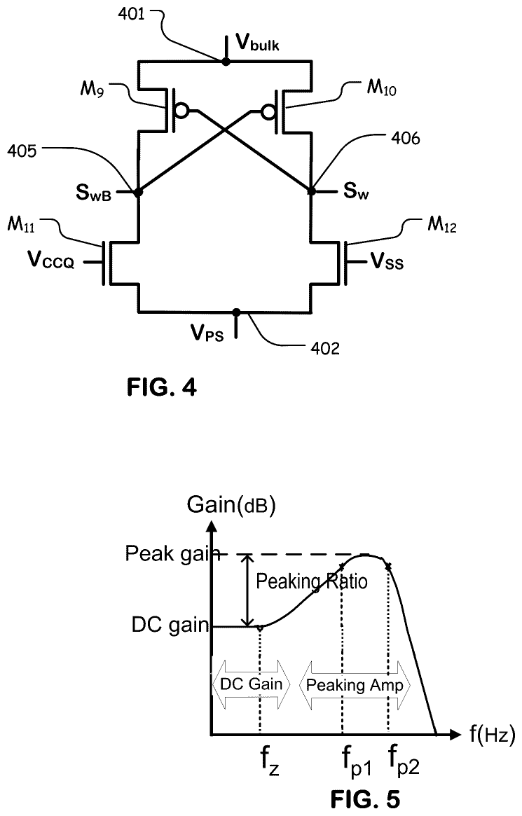

The gates of the transistors M_{R1} and M_{R2} of the resistor circuit are connected to a bias voltage SEN. As illustrated in the circuit, the bias voltage SEN can be provided by a switch 150 response to a control signal V_{EN} to provide a first state S_{wB} to enable the differential amplifier and to set transistors M_{R1} and M_{R2} in a triode operating region during operation, and a second state S_{w} to turn off transistors M_{R1} and M_{R2}. An example of a bias circuit to provide the voltages S_{wB} and S_{w} is described with reference to FIG. 4. The bias circuit can set S_{wB} to a voltage close to the common mode voltage of the input signals, and set S_{w} to a voltage close to V_{bulk}.

A capacitor circuit including at least one capacitor connected to the source of at least one of the transistors M₇ and M₈ at nodes 117 and 118, and in this example including source capacitor 121 and source capacitor 122 connected to the sources of the transistors M₇ and M₈. The source capacitor 121 is connected between node 117 and a reference node such as VSS or ground. The source capacitor 122 is connected between node 118 and the reference node. The capacitance (2C_{S}) of the capacitor circuit (source capacitors 121 and 122 in this example) is tuned along with the resistor circuit to set the frequency response of the differential amplifier.

A drain resistor having resistance R_{D} is connected between the drain of transistor M₇ at node 127 and the reference node. Also, a drain resistor having a resistance R_{D} is connected between the drain of transistor M₈ at node 128 and the reference node. In the circuit, parasitic capacitance C_{P} is illustrated across the drain resistors.

Input voltages D_{Q} and D_{QB} are applied at the gates of the input pair of transistors M₇ and M₈.

Output voltages V_{OUTN} and V_{OUTP} of the differential amplifier are generated at nodes 127 and 128, respectively.

A circuit having an input pair with source degeneration, like that illustrated in FIG. 2, can be applied as an amplifier with high voltage gain, such as an operational amplifier, and as an amplifier with high current gain, such as an operational transconductance amplifier. The inputs can be differential signals, or a single ended signal with a reference voltage applied to one of the transistors of the input pair.

It is desirable for the circuit to have a peaking ratio which remains constant across operating temperatures and process corners. The peaking ratio is defined as the ratio between the ideal peak gain and the DC gain of the circuit, and is a function of the effective gain gₘ of the input pair and the effective resistance R_{S} of the source side resistor circuit. For example, the peaking gain can be expressed by the following:

$$\frac{Ideal peak gain}{DC gain} = 1 + \frac{{g}_{m} {R}_{S}}{2} \approx 2$$

In the circuit illustrated, in operation the gate to source voltage of M₇ or M₈ is about equal to the gate to source voltage of M_{R1} and M_{R2}. As a result, R_{S} varies over temperature and process corners with gₘ in a manner that tends to maintain a constant peaking ratio. Accordingly, the input pair of transistors has an effective gain gₘ, and the resistor circuit has an effective resistance R_{S}, and the effective resistance R_{S} of the resistor circuit can vary with the gₘ over an operating range of temperature and process corners in a way tending to maintain a constant peaking ratio across the operating range in some embodiments.

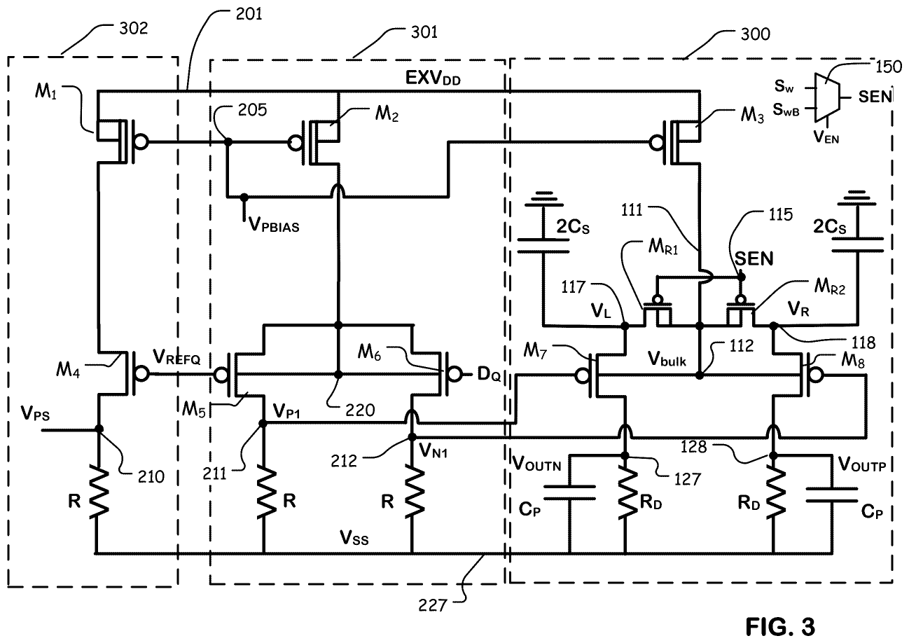

FIG. 3 is a circuit diagram for an equalizer circuit including an input pair of transistors with source degeneration using a resistor circuit having a transistor biased in a triode region, like that shown in FIG. 2. The equalizer circuit of FIG. 3 includes the differential amplifier 300, an input circuit 301 to convert a single ended input D_{Q} to a differential signal V_{N1}, V_{P1} to be applied as input to the differential amplifier 300, and a circuit 302 to provide a voltage V_{PS} which tracks the common mode voltage of the output of the input circuit 301. The differential amplifier 300 is like that of FIG. 2 with reference numerals of FIG. 2 applied and not described again. The inputs to the differential pair M₇ and M₈ are provided by the outputs V_{P1} and V_{N1} of the circuit 301. The current source 110 of FIG. 2 is provided by a P-channel current mirror transistor M₃, configured in a current mirror relationship with P-channel transistors M₁ and M₂ with its gate connected to node 205, and its source connected to node 201, which can be connected to a supply voltage, such as an external supply voltage EXV_{DD}. A voltage V_{PBAIS} is applied at node 205. The drain 111 of transistor M₃ is connected to node 112, which is the channel bodies or bulk terminal of transistors M_{R1}, M_{R2}, M₇ and M₈. Transistors M₁, M₂ and M₃ can be transistors that have small gate-to-source threshold voltage to improve supply voltage headroom.

Circuit 301 includes a pair of P-channel transistors M₅ and M₆, having source terminals coupled together at node 220. The channel bodies or bulk terminals of transistors M₅ and M₆ are also connected to node 220. Transistor M₂ is connected to provide current at node 220 configured in a current mirror relationship with transistors M₁ and M₃ with its gate connected to node 205, and its source connected to an external supply voltage EXV_{DD}. The drain terminals of transistors M₅ and M₆ are connected to nodes 211 and 212, respectively. A drain-side resistor having a resistance R is connected between node 211 and reference node 227. Also a drain-side resistor having a resistance R is connected between node 212 and reference node 227. Differential output voltages V_{P1} and V_{N1} are provided at nodes 211 and 212, respectively, which are in turn coupled to the gates of transistors M₇ and M₈, as mentioned above.

A single ended input signal D_{Q} is applied to the gate of transistor M₆. A reference voltage V_{REFQ} is applied to the gate of transistor M₅.

Circuit 302 includes P-channel transistor M₄ in series with a current mirror transistor M₁, configured in a current mirror relationship with transistors M₂ and M₃ with its gate connected to node 205, and its source connected to an external supply voltage EXV_{DD}. A voltage V_{PBAIS} is applied at node 205 from a bias circuit or other source of a voltage to implement the current mirror. A drain side resistor having resistance R is connected between the drain of transistor M₄ at node 210 and the reference node 227. Transistor M₄ can have the same dimensions as the differential pair M₅ and M₆. This circuit produces a node voltage V_{PS} at node 210 which tracks the common mode voltage of the signals V_{P1} and V_{N1} at nodes 211 and 212. The voltage V_{PS} can be used in a bias circuit like that shown in FIG. 4 that generates the control signal S_{wB} used to maintain the resistor circuit transistors in a triode region.

FIG. 4 is a circuit diagram of a circuit to produce bias voltages for the gates of the first transistor MR1 and the second transistor MR2 in the resistor circuit, including a bias voltage to bias the first transistor MR1 and the second transistor MR2 in a triode region. The circuit is implemented as level shifter in the bias circuit, which can be used to generate the bias voltages S_{w} and S_{wB}. The bias circuit includes a P-channel transistor M₉ in series with an N-channel transistor M₁₁ between node 401 and node 402. Also, the bias circuit includes a P-channel transistor M₁₀ in series with an N-channel transistor M₁₂ between node 401 and node 402. Node 401 is connected to the channel body node 112 in the circuit of FIG. 3, or otherwise receives voltage V_{bulk} generated at node 112. Node 402 is connected to node 210 at the drain of transistor M₄ in the circuit of FIG. 3, or otherwise receives the node voltage V_{PS}. Bias voltage S_{wB} is generated at node 405 between transistors M₉ and M₁₁. Bias voltage S_{w} is generated at node 406 between transistors M₁₀ and M₁₂.

The gates of transistors M₉ and M₁₀ are connected to nodes 406 and 405, respectively. The gate of transistor M₁₁ is connected to a supply voltage V_{CCQ}, while the gate of transistor M₁₂ is connected to the reference voltage V_{SS}. The supply voltage V_{CCQ} can be a regulated supply voltage generated on-chip.

The circuit of FIG. 4 maintains the voltage S_{wB} at node 405. The voltage S_{wB} is equal to, or close to, the common mode voltage V_{PS}. The circuit of FIG. 4 maintains the voltage S_{w} at node 406. The voltage S_{w} is equal to, or close to, the bulk voltage V_{bulk} at node 112, on the channel body terminal of the transistors in the resistor circuit. A switch connects voltage S_{wB} to node 115 to enable the resistance of the resistor circuit to track gain of the input pair, and connects voltage S_{w} to node 115 to turn off the resistor circuit.

When S_{wB} is applied to the gates of the transistors M_{R1} and M_{R2} at node 115, V_{L} is V_{bulk}−V_{DS} of M_{R1} and V_{R} is V_{bulk}−V_{DS} of M_{R2}. However, the V_{DS} values of M_{R1} and M_{R2} are small. So, V_{L} and V_{R} will be close to V_{bulk}.

In this circuit, when node 115 is set to S_{wB}, the gate-to-source voltage V_{GS} of the transistors M_{R1} and M_{R2} in the resistor circuit is V_{PS}−V_{bulk}. V_{PS} should be lower than V_{bulk} by an amount to set transistors M_{R1} and M_{R2} in the triode region.

FIG. 5 is a graph of gain versus frequency for a circuit like that of FIG. 3. As can be seen, there is essentially constant gain in the lower frequency range, referred to as the DC gain. The gain increases starting at frequency f_{z} to a target region between fₚ₁ and fₚ₂, in which a peak gain is achieved. A so-called peaking ratio is a circuit characteristic defined by the ratio of the peak gain to the DC gain. The DC gain and the peak gain of the circuit are functions of the transistor gain gₘ of the differential pair of transistors and the source resistance R_{S} generated by M_{R1} and M_{R2}. Using the circuit described herein, the transistor gain gₘ and the source resistance R_{S} can track across process corners.

Using an equalizer circuit as described herein, the peaking ratio can be maintained relatively constant over the target frequency range, across process corners. In a simulation for comparison of a circuit replacing the MOS transistors MR1 and MR2 of FIG. 3 with a physical resistor, to the circuit of FIG. 3, across typical, slow and fast process corners and temperatures ranging from −40 to 105 C, the peaking ratio range of the base circuit was 1.59 to 2.24 (variation of 0.65), while the peaking ratio range of the circuit like that of FIG. 3 was 1.86 to 2.14 (variation of 0.28).

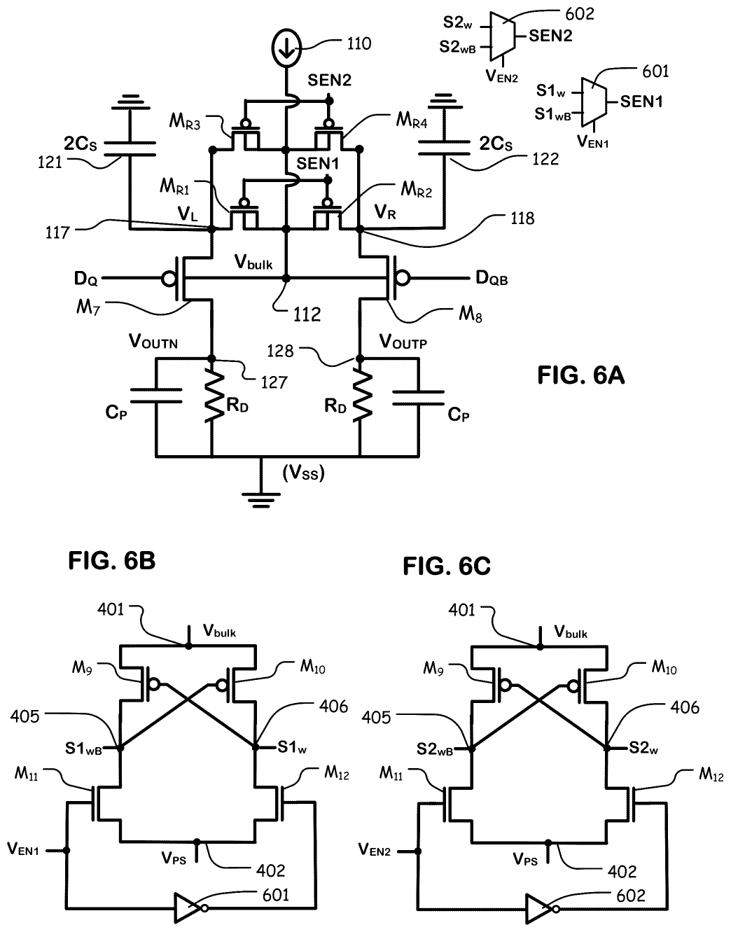

FIG. 6A is a circuit diagram for a differential amplifier including a resistor circuit configured as a source side resistance, like that of FIG. 2 and in which corresponding components have like reference numerals. The resistor circuit includes two pairs of p-channel transistors. The first pair includes M_{R1} and M_{R2}. The second pair includes M_{R3} and M_{R4}. Transistor M_{R1} has a first channel terminal (i.e., source/drain terminal) connected to the node 117 and a second channel terminal connected to the output of the current source 110 at node 112. Transistor M_{R2} has a first channel terminal connected to node 118 and a second channel terminal connected to node 112. Node 112 is connected to the output of the current source 110. Also, the channel bodies, or semiconductor “bulk”, of the transistors M₇ and M₈ of the input pair, and of the transistors M_{R1} and M_{R2} of the resistor circuit, are connected to node 112. The voltage at node 112 is labeled V_{bulk}. When transistor M_{R1} is on in a triode region, V_{L} is equal to V_{bulk}−(V_{DS} of M_{R1}). Also, when transistor M_{R2} is on in a triode region, V_{R} is equal to V_{bulk}−(V_{DS} of M_{R2}). When operated in the triode region, the drain to source voltage V_{DS} of transistors M_{R1} and M_{R2} varies linearly with V_{L} and V_{R} respectively.

The gates of the transistors M_{R1} and M_{R2} of the resistor circuit are connected to a first bias voltage SEN1. The bias voltage SEN1 can be provided by a switch 601 response to a first control signal V_{EN1} to provide a first state voltage S_{wB} to the differential amplifier and to the transistors M_{R1} and M_{R2}, biasing them in a triode operating region during operation, and a second state voltage S_{w} to transistors M_{R1} and M_{R2}, turning them off.

The transistors M_{R3} and M_{R4} can have different sizes than transistors M_{R1} and M_{R2}. In this example the transistors M_{R3} and M_{R4} can be larger transistors such that when operated the resistance provided is very low. This can maintain operation of the circuit when tracking is not used.

The gates of the transistors M_{R3} and M_{R4} of the resistor circuit are connected to a second bias voltage SEN2. The second bias voltage SEN2 can be provided by a switch 602 response to a control signal V_{EN2} to provide a first state S2_{wB} to set transistors M_{R3} and M_{R4} in a triode operating region during operation, and a second state S2w to turn off the transistors M_{R3} and M_{R4}.

An example of a bias circuit to provide the voltages S1_{wB} and S1w is described with reference to FIG. 6B. The bias circuit can set S1_{wB} to a voltage close to the common mode voltage of the input signals, and set S1_{w} to a voltage close to V_{bulk}. An example of a bias circuit to provide the voltages S2_{wB} and S2w is described with reference to FIG. 6C. The bias circuit can set S2_{wB} to a voltage close to the common mode voltage of the input signals, and set S2w to a voltage close to V_{bulk}.

FIGS. 6B and 6C are circuit diagrams of a circuit to bias the first transistor M_{R1} and the second transistor M_{R2} in the resistor circuit, and to bias the third transistor M_{R3} and the fourth transistor M_{R4} in the resistor circuit, respectively. The circuits are implemented as described with reference to FIG. 4 and not described again. These circuits differ in that a first enable signal EN1 is applied to the gate of transistor M11, and its inverse, generated by inverter 601, is applied to the gate of transistor M12, in the circuit of FIG. 6B, and a second enable signal EN2 is applied to the gate of transistor M11, and its inverse, generated by inverter 602, is applied to the gate of transistor M12, in the circuit of FIG. 6C.

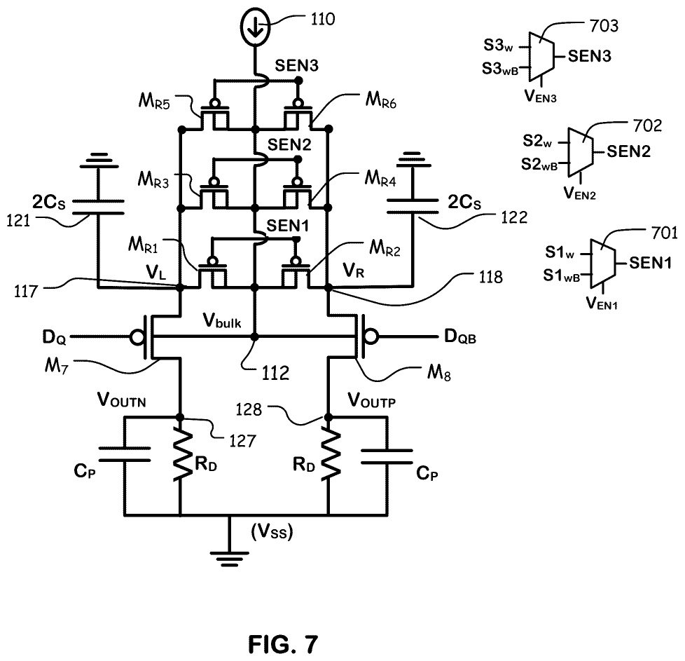

FIG. 7 is yet another example, having in this embodiment three pairs of transistors used in the resistor circuit. The first pair includes M_{R1} and M_{R2}. The second pair includes M_{R3} and M_{R4}. The third pair includes M_{R5} and M_{R6}. Transistor M_{R1} has a first channel terminal (i.e., source/drain terminal) connected to the node 117 and a second channel terminal connected to the output of the current source 110 at node 112. Transistor M_{R2} has a first channel terminal connected to node 118 and a second channel terminal connected to node 112. Node 112 is connected to the output of the current source 110. Also, the channel bodies, or semiconductor “bulk”, of the transistors M₇ and M₈ of the input pair, and of the transistors M_{R1} and M_{R2} of the resistor circuit, are connected to node 112. The voltage at node 112 is labeled V_{bulk}. When transistor M_{R1} is on in a triode region, V_{L} is equal to V_{bulk}−(V_{DS} of M_{R1}). Also, when transistor M_{R2} is on in a triode region, V_{R} is equal to V_{bulk}−(V_{DS} of M_{R2}). When operated in the triode region, the drain to source voltage V_{DS} of transistors M_{R1} and M_{R2} varies linearly with V_{L} and V_{R} respectively.

The gates of the transistors M_{R1} and M_{R2} of the resistor circuit are connected to a first bias voltage SEN1, provided for example by a selector 701 responsive to an enable signal V_{EN1}. As illustrated in the circuit, the first bias voltage has a first state S1_{wB} to enable the differential amplifier and to set transistors M_{R1} and M_{R2} in a triode operating region during operation, and a second state S1w to turn off the transistors M_{R1} and M_{R2}.

The transistors M_{R3} and M_{R4} can have different sizes than transistors M_{R1} and M_{R2}, and thereby cause different effects in the circuit. In this example the transistors M_{R3} and M_{R4} can be larger transistors such that when operated the resistance provided is very low. This can maintain operation of the circuit when tracking is not used.

The gates of the transistors M_{R3} and M_{R4} of the resistor circuit are connected to a second bias voltage SEN2, provided for example by a selector 702 responsive to an enable signal V_{EN2}. As illustrated in the circuit, the second bias voltage has a first state S2_{wB} to set transistors M_{R3} and M_{R4} in a triode operating region during operation, and a second state S2w to turn off the transistors M_{R3} and M_{R4}.

The transistors M_{R5} and M_{R6} can have different sizes similar to transistors M_{R1} and M_{R2}, and thereby cause slightly different effects in the circuit. In this example the transistors M_{R5} and M_{R6} can be sized in a manner that provides for tuning the tracking characteristic by changing between the first and third pairs.

The gates of the transistors M_{R5} and M_{R6} of the resistor circuit are connected to a third bias voltage SEN3, provided for example by a selector 703 responsive to an enable signal V_{EN3}. The selection of the pair of transistors to be operable in the circuit can be accomplished using independent enable signals to the bias circuits, like that described with reference to FIGS. 6B and 6C.

In general, embodiments of the technology can include source side resistor circuits comprising a plurality of pairs of transistors, selected for different effects on the characteristics of the output signals to be produced.

The embodiments described herein are based on amplifiers with an input pair using P-channel transistors (PMOS). In alternative systems, N-channel transistors (NMOS) could be utilized, changing the current mirror transistors and the transistors in the source-side resistor circuit to NMOS transistors. Also, the source resistor, drain resistor and current mirror positions are inverted. P-channel embodiments are preferred in lower voltage systems.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. An amplifier circuit, comprising:
an input pair of transistors, the transistors in the pair having respective source, drain, gate and bulk terminals; and
a resistor circuit connected to the sources of the transistors in the input pair, the resistor circuit including a transistor.

2. The amplifier circuit of claim 1, including:
a circuit to bias the transistor in the resistor circuit in a triode region.

3. The amplifier circuit of claim 1, wherein the transistor in the resistor circuit has source, drain, gate and bulk terminals, and wherein the bulk terminal of the transistor and the bulk terminal of the transistors in the input pair are connected together.

4. The amplifier circuit of claim 1, including a current source connected to provide current through the resistor circuit to the input pair.

5. The amplifier circuit of claim 4, wherein the resistor circuit includes a second transistor, and wherein the first-mentioned transistor in the resistor circuit and the second transistor have gates connected to a bias node, sources connected to the current source and drains connected to respective sources of the transistors in the input pair.

6. The amplifier circuit of claim 5, wherein the bulk terminals of the first mentioned transistor in the resistor circuit and the second transistor, and the bulk terminals of the transistors in the input pair, are connected together.

7. The amplifier circuit of claim 6, including:
a circuit to bias the first mentioned transistor in the resistor circuit and the second transistor in a triode region.

8. The amplifier circuit of claim 1, including a capacitor circuit connected to the source of at least one of the transistors in the input pair.

9. The amplifier circuit of claim 1, wherein the input pair of transistors has an effective gain gₘ, and the resistor circuit has an effective resistance R_{S}, and the effective resistance R_{S} of the resistor circuit can vary with the gₘ over an operating range of temperature and process corners in a way tending to maintain a constant peaking ratio across the operating range.

10. An amplifier circuit, comprising:
an input pair of transistors, the transistors in the pair having respective source, drain, gate and bulk terminals;
a resistor circuit connected to the sources of the transistors in the input pair, the resistor circuit including:
a first MOS transistor having a first channel terminal connected to the source of a first transistor in the input pair, and a second channel terminal connected to the bulk terminal of the first transistor in the input pair; and
a second MOS transistor having a first channel terminal connected to the source of a second transistor in the input pair, and a second channel terminal connected to the bulk terminal of the second transistor in the input pair;
circuits to bias the first MOS transistor and the second MOS transistor in a triode region; and
a current source connected to provide current through the resistor circuit to the input pair.

11. The amplifier circuit of claim 10, wherein the current source is connected to the bulk terminals of the first and second transistors in the input pair.

12. The amplifier circuit of claim 10, wherein the resistor circuit includes a plurality of pairs of MOS transistors, including a first pair consisting of the first and second transistors, and including circuits to selectively apply gate voltages to the plurality of pairs to enable one of the pairs.

13. The amplifier circuit of claim 10, including an input circuit to translate a single ended signal to a differential signal, and to connect the differential signals to the gates of the input pair of transistors.

14. The amplifier circuit of claim 10, wherein the circuits to bias the first MOS transistor and the second MOS transistor include:
a circuit to produce a node voltage to track a common mode voltage of differential input signals applied to the input pair; and
a circuit to produce bias voltages, in response to the node voltage, for the gates of the first and second MOS transistors of the resistor circuit.

15. The amplifier circuit of claim 14, wherein the circuit to produce the node voltage is coupled to the input circuit.

16. The amplifier circuit of claim 14, wherein the circuit to produce bias voltages includes a level shifter.

17. The amplifier circuit of claim 10, including a capacitor circuit connected to the source of at least one of the transistors in the input pair.

18. The amplifier circuit of claim 10 the input pair of transistors has an effective gain gₘ, and the resistor circuit has an effective resistance R_{S}, and the effective resistance R_{S} of the resistor circuit can vary with the gₘ over an operating range of temperature and process corners in a way tending to maintain a constant peaking ratio across the operating range.

19. A method to receive an input signal, comprising:
applying the input signal to an equalizer that includes an input pair of transistors, the transistors in the pair having respective source, drain, gate and bulk terminals, and a resistor circuit connected to the sources of the transistors in the input pair, the resistor circuit including a transistor having source, drain, gate and bulk terminals, and wherein the bulk terminal of the transistor in the resistor circuit and the bulk terminal of at least one of the transistors in the input pair are connected together; and
biasing the transistor in the resistor circuit in a triode region.

20. The method of claim 19, including applying an output of the equalizer to a receiver.
